(19) United States
(12) Patent Application Publication
(10) Pub. No.: US 2023/0278877 A1
(43) Pub. Date: Sep. 7, 2023

(54) SILICON CARBON COMPOSITE PARTICLES

(71) Applicant: WACKER CHEMIE AG, Munich (DE)

(72) Inventors: Alena KALYAKINA, München (DE); Christoph DRÄGER, München (DE); Claudia KLEINLEIN, Burghausen (DE); Jürgen PFEIFFER, Mehring (DE); Jan TILLMANN, München (DE)

(73) Assignee: Wacker Chemie AG, Munich (DE)

(21) Appl. No.: 18/019,845

(22) PCT Filed: Apr. 16, 2021
(86) PCT No.: PCT/EP2021/059963

§ 371 Date: Feb. 6, 2023

(51) Int. Cl. C01B 33/029; H01M 10/0525; H01M 4/38; H01M 4/36; H01M 4/587

(52) U.S. Cl. CPC C01B 33/029; H01M 4/366; H01M 4/386; H01M 4/587; H01M 10/0525; C01P 2004/51; C01P 2006/12; C01P 2006/14; H01M 2300/002

(57) ABSTRACT

Silicon carbon composite particles and anode materials for use within lithium-ion batteries utilizing the silicon carbon composite particles. Where the silicon carbon composite particles have an alkali metal or alkaline earth metal concentration of 0.05 to 10 wt% and a pH > 7.5.

The present invention relates to silicon-carbon composite particles based on porous particles and silicon, to processes for producing the silicon-carbon composite particles, and to the use thereof as active materials in anodes for lithium-ion batteries.

As storage media for electrical power, the practical electrochemical energy stores having the highest energy densities are currently lithium-ion batteries. Lithium-ion batteries are utilized primarily in the area of portable electronics, for tools and also for electrically driven transportation means, such as bicycles, scooters or automobiles. A widespread material currently for the negative electrode (“anode”) of such batteries is graphitic carbon. A disadvantage, however, is the relatively low electrochemical capacity of such graphitic carbons, which is theoretically at most 372 mAh per gram of graphite and therefore corresponds only to about a tenth of the electrochemical capacity theoretically achievable with lithium metal. Alternative active materials for the anode use an addition of silicon, as described for example in EP 3335262 B1. With lithium, silicon forms binary, electrochemically active alloys which enable very high electrochemically achievable lithium contents of up to 4200 mAh per gram of silicon.

The intercalation and deintercalation of lithium ions in silicon is associated with the disadvantage of an accompanying very sharp change in volume, which in the case of complete intercalation can reach up to 300%. Such changes in volume subject the silicon-containing active material to severe mechanical loading, possibly resulting in the active material ultimately breaking apart. In the active material and in the electrode structure, this process, also referred to as electrochemical grinding, leads to a loss of the electrical contacting and hence to the sustained, irreversible loss of capacity on the part of the electrode.

Additionally, the surface of the silicon-containing active material reacts with constitutes of the electrolyte to continuously form passivating protective layers (solid electrolyte interphase; SEI). The components formed are no longer electrochemically active. The lithium bound within them is no longer available to the system, so leading to a pronounced and continuous loss of capacity on the part of the battery. Because of the extreme change in volume of the silicon during battery charging/discharging, the SEI regularly breaks up, meaning that further, as yet unoccupied surfaces of the silicon-containing active material are exposed, and are then subject to further SEI formation. In the complete cell, the amount of mobile lithium, which corresponds to the useful capacity, is limited by the cathode material and consequently is increasingly consumed, and after just a few cycles, the capacity of the cell drops to an extent unacceptable from a performance standpoint.

The reduction in capacity in the course of multiple charging and discharging cycles is also referred to as fading or continuous capacity loss, and is generally irreversible.

A series of silicon-carbon composite particles have been described for use as silicon-containing active materials for anodes of lithium-ion batteries. In this case, silicon-carbon composite particles are obtained, for example, starting from gaseous or liquid silicon precursors, by thermal decomposition of the latter, with deposition of silicon in porous carbon particles. For example, US 10,147,950 B2 describes deposition of silicon from monosilane, SiH₄, in porous carbon particles in a tube furnace or comparable furnace type at elevated temperatures of 300 to 900° C., preferably with agitation of the particles, through a process of CVD (“chemical vapor deposition”) or PE-CVD (“plasma-enhanced chemical vapor deposition”). Even the composites obtainable in this way have cycling stabilities which are not sufficient for use in demanding applications. The deposition of the silicon, moreover, requires high temperatures and/or long reaction times, so necessitating very high expenditure of energy and time.

A feature shared by the known silicon-carbon composite particles, therefore, is that when the silicon-carbon composite particles are used as active material in anodes for lithium-ion batteries, already exhibit low capacity losses in electrochemical cycling, thus having a good cycling stability as a result of low fading. For certain areas of application, especially in use in batteries for electrically driven motor vehicles, however, the cycling stability achieved is not sufficient and must be increased further.

Against this background, the object was to provide silicon-carbon composite particles which, when used as active material in anodes of lithium-ion batteries, exhibit a very low initial and continuous loss of lithium available in the cell and therefore enable high coulombic efficiencies and high cycling stabilities as a result of a stable electrochemical behavior. The fading ought preferably to be minimal.

This object has surprisingly been achieved with silicon-carbon composite particles having an alkali metal or alkaline earth metal concentration of 0.05-10 wt% and a pH > 7.5. In use as active materials for lithium-ion batteries, such silicon-carbon composite particles have significantly increased cycling stabilities, so leading to reduced fading. It has surprisingly been observed, moreover, that in production of silicon-carbon composite particles by deposition of silicon into porous carbon particles, starting from gaseous or liquid silicon precursors, in analogy to the above-described CVD process, a significantly increased reaction rate can be observed if the porous carbon itself has an alkali metal or alkaline earth metal concentration of > 0.1 to 20 wt% and a pH of > 7.5.

A subject of the invention is silicon-carbon composite particles having
a) an alkali metal or alkaline earth metal concentration of 0.05 to 10 wt% and
b) a pH > 7.5.

The porous carbon particles preferably having an alkali metal or alkaline earth metal concentration of 0.1 to 20 wt%, more preferably of 0.2 to 10 wt%, and most preferably of 0.3 to 5 wt%. The alkali metal and alkaline earth metal concentrations of the porous carbon particles can be determined quantitatively by ICP emission spectroscopy using, for example, the Optima 7300 DV instrument from Perkin Elmer.

Any desired processes can be employed for producing the silicon-carbon composite particles of the invention. In particular, production by deposition of silicon from gaseous or liquid silicon precursors by infiltration into porous carbon particles, in analogy to the process described in US 10,147,950 B2, is a suitable route to the silicon-carbon composite particles of the invention.

Another subject of the invention is a process for producing the silicon-carbon composite particles of the invention by silicon infiltration from silicon precursors which are selected from silicon precursors which are liquid or gaseous at 20° C. and 1013 mbar, in the presence of porous carbon particles having an alkali metal or alkaline earth metal concentration of 0.1 to 20 wt% and a pH of > 7.5.

In this process, silicon is deposited in the pores and on the surface of the porous carbon particles.

The deposition of silicon by thermal decomposition from gaseous or liquid silicon precursors into pores and on the surface of the porous carbon particles is referred to here as silicon infiltration.

Identical or different silicon precursors can be reacted with identical or different porous carbon particles.

Porous carbon particles having an alkali metal or alkaline earth metal concentration of 0.1 to 20% and a pH of > 7.5 can be obtained in any desired way known to the skilled person. The porous carbon particles having an alkali metal or alkaline earth metal concentration of 0.1 to 20% and a pH of > 7.5 are preferably obtained by treating porous carbon particles with basic alkali metal or alkaline earth metal compounds.

Preferred basic alkali metal or alkaline earth metal compounds are hydroxides, carbonates, hydrogen carbonates, percarbonates, amides, alkoxides, phenoxides, alkylates, hydrides, alkides, silicates, disulfites, fluorides, cyanides, nitrites, peroxides, hyperoxides. Preference is given to hydroxides, carbonates, hydrogen carbonates, percarbonates, hydrides, fluorides and amides, particular preference to hydroxides, carbonates, hydrogen carbonates, amides, hydrides, complex hydrides (tetrahydrometallates, e.g., BH₄ or AlH₄ with, e.g., Li, Na, K, Mg, Ca as counterion, e.g., LiBH₄, NaBH₄, Li₂Zn(BH₄)_{4.}), and preference above all to hydroxides, carbonates, and hydrogen carbonates. The preferred basic alkali metal or alkaline earth metal compounds may be used alone or else as mixtures of different basic alkali metal and/or alkaline earth metal compounds.

The production of the porous carbon particles having an alkali metal or alkaline earth metal concentration of 0.1 to 20% and a pH of > 7.5 may alternatively be realized by treating the porous carbon particles with a solution of the basic alkali metal or alkaline earth metal compounds. Solvents used for the basic alkali metal or alkaline earth metal compounds may be water, liquid ammonia, ketones such as acetone, alcohols such as ethanol, methanol, propanol, butanol, glycerol, hydrocarbons such as toluene, styrene, benzene, heterocycles such as pyridine or bipyridine, nitriles such as acetonitrile, sulfoxide such as dimethyl sulfoxide, and ethers such as tetrahydrofuran and 1,4-dioxane. Preferred solvents include water and alcohols such as ethanol, methanol, propanol or butanol, particular preference being given to the use of water and ethanol, most preferably water.

Based on the carbon present in the porous carbon particles, the porous carbon particles and the basic alkali and/or alkaline earth metal compounds may be used in any desired molar ratios. The porous carbon particles and the basic alkali metal or alkaline earth metal compounds are used preferably in a molar ratio of 100:1 to 5:1, more preferably in a 50:1 to 5:1 molar ratio, and most preferably in a molar ratio of 20:1 to 5:1, based on the carbon present in the form of carbon particles.

The porous carbon particles may be treated with the basic alkali metal or alkaline earth metal compound at temperatures below 20° C., above 20° C. or at 20° C.; the treatment takes place preferably at elevated temperature. The temperature when treating the porous carbon particles with the basic alkali metal or alkaline earth metal compound is preferably between 30 and 200° C., more preferably 50 to 160° C., and very preferably 70 to 120° C.

The porous carbon particles may be treated with the basic alkali metal or alkaline earth metal compound under reduced pressure, atmospheric pressure or elevated pressure. The treatment takes place preferably at atmospheric pressure or elevated pressure of up to 5 bar, more preferably at atmospheric pressure.

The porous carbon particles may be treated with the solution of the basic alkali metal or alkaline earth metal compound in any desired reactors suitable for the treatment. More particularly, the treatment takes place with stirring of the suspension of the porous carbon particles in the solution of the basic alkali metal or alkaline earth metal compound, or by spraying the porous carbon particles with a solution of the basic alkali metal or alkaline earth metal compounds.

After the treatment of the porous carbon particles with the basic alkali metal or alkaline earth metal compounds, the porous carbon particles are preferably freed from the solution of the basic alkali metal or alkaline earth metal compounds. This may take place, for example, by filtration or centrifuging; the treated porous carbon particles are optionally purified by water washing to remove excess basic alkali metal or alkaline earth metal compound. Alternatively, the treated porous carbon particles may be obtained by evaporating the solvent for the basic alkali metal or alkaline earth metal compound.

Prior to reaction with the gaseous or liquid silicon precursor, the porous carbon particles are preferably dried.

Drying of the porous carbon particles may take place at elevated temperature of 50 to 400° C. under inert gas atmosphere in any desired reactor suitable for drying. Intergases used may be nitrogen or argon, for example. Drying may alternatively take place at elevated temperature of 50 to 400° C. and reduced pressure of 0.001 to 900 mbar. The drying time is preferably 0.1 second to 12 hours. The porous carbon particles may be dried in the same reactor as the reaction with the gaseous or liquid silicon precursor, or in a separate reactor suitable for drying.

The porous carbon particles preferably possess a density as determined by helium pycnometry of 0.1 to 4 g/cm³ and more preferably of 0.3 to 3 g/cm³.

The porous carbon particles have a volume-weighted particle size distribution with diameter percentiles d₅₀ of preferably ≥ 0.5 µm, more preferably ≥ 1.5 µm, and most preferably ≥ 2 µm. The diameter percentiles d₅₀ are preferably ≤ 20 µm, more preferably ≤ 12 µm, and most preferably ≤ 8 µm.

The volume-weighted particle size distribution of the porous carbon particles is preferably between the diameter percentiles d₁₀ ≥ 0.2 µm and d₉₀ ≤ 20.0 µm, more preferably between d₁₀ ≥ 0.4 µm and d₉₀ ≤ 15.0 µm, and most preferably between d₁₀ ≥ 0.6 µm to d₉₀ ≤ 12.0 µm.

The porous carbon particles have a volume-weighted particle size distribution with diameter percentiles d₁₀ of preferably ≤ 10 µm, more preferably ≤ 5 µm, especially preferably ≤ 3 µm, and most preferably ≤ 2 µm. The diameter percentiles d₁₀ are preferably ≥ 0.2 µm, more preferably ≥ 0.4, and most preferably ≥ 0.6 µm.

The porous carbon particles have a volume-weighted particle size distribution with diameter percentiles d₉₀ of preferably ≥ 4 µm and more preferably ≥ 8 µm. The diameter percentiles d₉₀ are preferably ≤ 20 µm, more preferably ≤ 15, and most preferably ≤ 12 µm.

The volume-weighted particle size distribution of the porous carbon particles has a d₉₀-d₁₀ span of preferably ≤ 15.0 µm, more preferably ≤ 12.0 µm, very preferably ≤ 10.0 µm, especially preferably ≤ 8.0 µm, and most preferably ≤ 4.0 µm. The volume-weighted particle size distribution of the porous carbon particles has a d₉₀-d₁₀ span of preferably ≥ 0.6 µm, more preferably ≥ 0.7 µm, and most preferably ≥ 1.0 µm.

The volume-weighted particle size distribution is determinable according to ISO 13320 by static laser scattering using the Mie model with the Horiba LA 950 instrument, with ethanol as dispersing medium for the porous particles.

The porous carbon particles may be in isolated or agglomerated form, for example. The porous carbon particles are preferably not aggregated and preferably not agglomerated. Aggregated means generally that in the course of the production of the porous carbon particles, initially primary particles are formed and undergo fusion, and/or primary particles are linked to one another via covalent bonds, for example, and in this way form aggregates. Primary particles are generally isolated particles. Aggregates or isolated particles can form agglomerates. Agglomerates are a loose coalition of aggregates or primary particles, which are linked to one another for example via van der Waals interactions or hydrogen bonds. Agglomerated aggregates can easily be split back into aggregates by conventional kneading and dispersing techniques. Aggregates cannot be disintegrated, or can be disintegrated only partly, into primary particles by these techniques. The presence of the porous particles in the form of aggregates, agglomerates or isolated particles can be visualized, for example, by conventional scanning electron microscopy (SEM). Static light scattering methods for determining the particle size distributions or particle diameters of particles are unable, in contrast, to distinguish between aggregates or agglomerates.

The porous particles may have any desired morphology and may therefore, for example, be splintery, platey, spherical or else acicular, with splintery or spherical porous carbon particles being preferred.

The morphology may be characterized, for example, by the sphericity ψ or the sphericity S. According to the Wadell definition, the sphericity ψ is the ratio of the surface area of a sphere of equal volume to the actual surface area of a body. In the case of a sphere, the value of ψ is 1. According to this definition, the porous particles have a sphericity ψ of preferably 0.3 to 1.0, more preferably of 0.5 to 1.0, and most preferably of 0.65 to 1.0.

The sphericity S is the ratio of the circumference of an equivalent circle with the same area A as the projection of the particle projected onto a surface, to the measured circumference U of this projection:

$$S = 2 \sqrt{π A} / U .$$

In the case of a particle of ideal circularity, the value of S would be 1. For the porous particles, the sphericity S is in the range from preferably 0.5 to 1.0 and more preferably from 0.65 to 1.0, based on the percentiles S₁₀ to S₉₀ of the numerical sphericity distribution. The sphericity S is measured, for example, from optical micrographs of individual particles or preferably, in the case of particles < 10 µm, with a scanning electron microscope, by graphic evaluation using image analysis software, such as ImageJ, for example.

The porous carbon particles preferably have a gas-accessible pore volume of ≥ 0.2 cm³/g, more preferably ≥ 0.6 cm³/g, and most preferably ≥ 1.0 cm³/g. This is beneficial for obtaining lithium-ion batteries with a high capacity. The gas-accessible pore volume is determined by gas adsorption measurements with nitrogen in accordance with DIN 66134.

The porous carbon particles are preferably open-pore. Open-pore means generally that pores are connected to the surface of the particles, via channels, for example, and can preferably be transfer mass, especially exchange gaseous components, with the surroundings. This can be verified using gas sorption measurements (evaluation according to Brunauer, Emmett and Teller, “BET”), i.e., of the specific surface area.

The porous carbon particles have specific surface areas of preferably ≥ 50 m²/g, more preferably ≥ 500 m²/g, and most preferably ≥ 1000 m²/g. The BET surface area is determined according to DIN 66131 (with nitrogen).

The pores of the porous carbon particles may have any desired diameters, i.e., generally, in the range of macropores (> 50 nm), mesopores (2 to 50 nm), and micropores (< 2 nm). The porous carbon particles can be used in any mixtures of different pore types. Preference is given to using porous particles having at most 30% of macropores, based on the total pore volume, more preferably porous carbon particles without macropores, and very preferably porous carbon particles with at least 50% of pores having a mean pore diameter below 5 nm. With more particular preference the porous carbon particles comprise exclusively pores having a pore diameter of less than 2 nm (method of determination: pore size distribution by BJH (gas adsorption) according to DIN 66134 in the mesopore range and according to Horvath-Kawazoe (gas adsorption) according to DIN 66135 in the micropore range; the pore size distribution in the macropore range is evaluated by mercury porosimetry according to DIN ISO 15901-1).

The porous carbon particles have a pH of preferably > 7.5, more preferably of > 8.5, and very preferably > 9. The pH of the porous carbon particles may be determined by ASTM standard number D1512, method A.

The porous carbon particles have alkali metal or alkaline earth metal concentrations of 0.05 to 10 wt%, preferably of 0.1 to 5 wt%, and more preferably 0.15 to 2.5 wt%.

The silicon-carbon composite particles of the invention have alkali metal or alkaline earth metal concentrations of 0.05 to 10 wt%, preferably of 0.1 to 5 wt%, and more preferably 0.15 to 2.5 wt%. The alkali metal and alkaline earth metal concentrations of the silicon-carbon composite particles of the invention may be determined by means of ICP emission spectroscopy using, for example, the Optima 7300 DV instrument from Perkin Elmer.

The silicon-carbon composite particles of the invention have pH values of > 7.5, preferably of > 8.5, and most preferably of > 9. The pH of the silicon-carbon composite particles of the invention may be determined by means of ASTM standard number D1512, method A.

The silicon-carbon composite particles of the invention have a volume-weighted particle size distribution with diameter percentiles d₅₀ preferably in a range from 0.5 to 20 µm. The d₅₀ value is ≥ 1.5 µm and more preferably ≥ 2 µm. The diameter percentiles d₅₀ are preferably ≤ 13 µm and more preferably ≤ 8 µm.

The volume-weighted particle size distribution of the silicon-carbon composite particles of the invention is preferably between the diameter percentiles d₁₀ ≥ 0.2 µm and d₉₀ ≤ 20.0 µm, more preferably between d₁₀ ≥ 0.4 µm and d₉₀ ≤ 15.0 µm, and most preferably between d₁₀ ≥ 0.6 µm to d₉₀ ≤ 12.0 µm.

The silicon-carbon composite particles of the invention have a volume-weighted particle size distribution with diameter percentiles d₁₀ of preferably ≤ 10 µm, more preferably ≤ 5 µm, especially preferably ≤ 3 µm, and most preferably ≤ 1 µm. The diameter percentiles d₁₀ are preferably ≥ 0.2 µm, more preferably ≥ 0.4 µm, and most preferably ≥ 0.6 µm.

The silicon-carbon composite particles of the invention have a volume-weighted particle size distribution with diameter percentiles d₉₀ of preferably ≥ 5 µm and more preferably ≥ 10 µm. The diameter percentiles d₉₀ are preferably ≤ 20.0 µm, more preferably ≤ 15.0 µm, and most preferably ≤ 12.0 µm.

The volume-weighted particle size distribution of the silicon-carbon composite particles of the invention has a d₉₀-d₁₀ span of preferably ≤ 15.0 µm, particularly preferably ≤ 12.0 µm, more preferably ≤ 10.0 µm, especially preferably ≤ 8.0 µm and most preferably ≤ 4.0 µm. The volume-weighted particle size distribution of the The silicon-carbon composite particles of the invention has a d₉₀-d₁₀ span of preferably ≥ 0.6 µm, more preferably ≥ 0.7 µm, and most preferably ≥ 1.0 µm.

The silicon-carbon composite particles of the invention are preferably in the forms of particles. The particles may be in isolated or agglomerated form. The silicon-carbon composite particles of the invention are preferably not aggregated and preferably not agglomerated. The terms isolated, agglomerated, and not aggregated have already been defined earlier on above in relation to the porous carbon particles. The presence of silicon-carbon composite particles of the invention in the form of aggregates or agglomerates may be visualized by means, for example, of conventional scanning electron microscopy (SEM).

The silicon-carbon composite particles of the invention may have any desired morphology, thus being, for example, splintery, platey, spherical or else acicular, with splintery or spherical particles being preferred.

According to the Wadell definition, the sphericity ψ is the ratio of the surface area of a sphere of equal volume to the actual surface area of a body. In the case of a sphere, the value of ψ is 1. According to this definition, the silicon-carbon composite particles of the invention have a sphericity ψ of preferably 0.3 to 1.0, more preferably of 0.5 to 1.0, and most preferably of 0.65 to 1.0.

The sphericity S is the ratio of the circumference of an equivalent circle of the same area A as the projection of the particle projected onto a surface, to the measured circumference U of this projection:

$$S = 2 \sqrt{π A} / U .$$

In the case of a particle of ideal circularity, the value of S would be 1. For the silicon-carbon composite particles of the invention, the sphericity S is in the range from preferably 0.5 to 1.0 and more preferably from 0.65 to 1.0, based on the percentiles S₁₀ to S₉₀ of the numerical sphericity distribution. The sphericity S is measured, for example, from optical micrographs of individual particles or preferably, in the case of particles of < 10 µm, with a scanning electron microscope, by graphic evaluation by means of image analysis software, such as ImageJ, for example.

The cycling stability of lithium-ion batteries can be further boosted via the morphology, the material composition, in particular the specific surface area or the internal porosity, of the silicon-carbon composite particles of the invention.

The silicon-carbon composite particles of the invention contain preferably 10 to 90 wt%, more preferably 20 to 80 wt%, very preferably 30 to 60 wt%, and especially preferably 40 to 50 wt% of silicon obtained via silicon infiltration, based on the total weight of the silicon-carbon composite particles of the invention (determined preferably by elemental analysis, such as ICP-OES).

The volume of the silicon obtained via infiltration in the silicon-carbon composite particles of the invention is obtained from the mass fraction of the silicon obtained via infiltration from the silicon precursor, as a proportion of the total mass of the silicon-carbon composite particles of the invention, divided by the density of silicon (2.336 g/cm³).

The pore volume P of the silicon-carbon composite particles of the invention is obtained from the sum total of gas-accessible and gas-inaccessible pore volume. The gas-accessible pore volume according to Gurvich of the silicon-carbon composite particles of the invention can be determined by gas sorption measurements with nitrogen in accordance with DIN 66134.

The gas-inaccessible pore volume of the silicon-carbon composite particles of the invention can be determined using the formula: gas-inaccessible pore volume = 1/skeletal density - 1/pure-material density.

The skeletal density here is the density of the silicon-carbon composite as determined by helium pycnometry according to DIN 66137-2; the pure-material density of the silicon-carbon composite particles of the invention is a theoretical density which can be calculated from the sum total of the theoretical pure-material densities of the components contained in the silicon-carbon composite particles of the invention, multiplied by their respective weight-based percentage fraction in the overall material. Accordingly, for a silicon-carbon composite particle: Pure-material density = theoretical pure-material density of silicon (2.336 g/cm³) * fraction of silicon in wt% + density of porous carbon particles (determined by helium pycnometry) * fraction of the porous carbon particles in wt%.

The pore volume P of the silicon-carbon composite particles of the invention is in the range from preferably 0 to 400 vol%, more preferably in the range from 100 to 350 vol%, and very preferably in the range from 200 to 350 vol%, based on the volume of the silicon obtained from silicon infiltration and present in the silicon-carbon composite particles of the invention.

The porosity present in the silicon-carbon composite particles of the invention may be either gas-accessible or gas-inaccessible. The ratio of the volume of gas-accessible to gas-inaccessible porosity of the silicon-carbon composite particles of the invention may be situated generally in the range from 0 (no gas-accessible pores) to 1 (all pores are gas-accessible). The ratio of the volume of gas-accessible to gas-inaccessible porosity of the silicon-carbon composite particles of the invention is preferably in the range from 0 to 0.8, more preferably is in the range from 0 to 0.3, and especially preferably of 0 to 0.1.

The pores of the silicon-carbon composite particles of the invention may have any desired diameters, being situated, for example in the range of macropores (> 50 nm), mesopores (2 to 50 nm), and micropores (< 2 nm). The silicon-carbon composite particles of the invention may also comprise any desired mixtures of different pore types. The silicon-carbon composite particles of the invention preferably contain at most 30% of macropores, based on the total pore volume, particular preference being given to silicon-carbon composite particles of the invention without macropores, and very particular preference to silicon-carbon composite particles of the invention having at least 50% of pores with a mean pore diameter below 5 nm. With more particular preference the silicon-carbon composite particles of the invention have exclusively pores with a diameter of at most 2 nm.

The silicon-carbon composite particles of the invention preferably comprise silicon structures which in at least one dimension have structural sizes of preferably at most 1000 nm, more preferably less than 100 nm, very preferably less than 5 nm (method of determination: scanning electron microscopy (SEM) and/or high-resolution transmission electron microscopy (HR-TEM)).

The silicon-carbon composite particles of the invention, in pores and on the outer surface, preferably comprise silicon layers having a layer thickness at most of 1000 nm, more preferably less than 100 nm, very preferably less than 5 nm (method of determination: scanning electron microscopy (SEM) and/or high-resolution transmission electron microscopy (HR-TEM)). The silicon-carbon composite particles of the invention may also comprise silicon in the form of layers formed from silicon particles. Silicon particles have a diameter of preferably at most 1000 nm, more preferably less than 100 nm, very preferably less than 5 nm (method of determination: scanning electron microscopy (SEM) and/or high-resolution transmission electron microscopy (HR-TEM)). The figure for the silicon particles here is based preferably on the diameter of the circle around the particles in a microscope image.

The silicon-carbon composite particles of the invention have a specific surface area of most 100 m²/g, preferably less than 60 m²/g, and especially preferably less than 20 m²/g. The BET surface area is determined according to DIN 66131 (with nitrogen). Accordingly, when the silicon-carbon composite particles of the invention are used as active material in anodes for lithium-ion batteries, SEI formation can be reduced and the initial coulombic efficiency can be enhanced.

The silicon in the silicon-containing material, deposited from the silicon precursor, may further comprise dopants, selected for example from the group containing Fe, Al, Cu, S, Cl, Zr, Ti, Pt, Ni, Cr, Sn, Ag, Co, Zn, B, P, Sb, Pb, Ge, Bi, rare earths, or combinations thereof. Preference here is given to Li and/or Sn. The amount of dopants in the material containing silicon-carbon composite particles is preferably at most 1 wt% and more preferably at most 100 ppm, based on the total weight of the silicon-carbon composite particles, determinable by means of ICP-OES.

The silicon-carbon composite particles of the invention generally have a surprisingly high stability under compressive stress and/or shear stress. The pressure stability and shear stability of the silicon-carbon composite particles of the invention is manifested here, for example, by the fact that the silicon-carbon composite particles of the invention exhibit only minor changes or none in their porous structure in SEM under compressive stress (for example, on electrocompaction) and, respectively, shear stress (for example, on electrode preparation).

The silicon-carbon composite particles of the invention may be produced in any desired reactors customary for silicon infiltration. Preferred reactors are those selected from fluidized bed reactors, rotary tube furnaces, which may be oriented in any desired arrangement from horizontal through vertical, and fixed-bed reactors, which may be operated as opened or closed systems, in the form of pressure reactors, for example. Particularly preferred reactors are those which enable uniform mixing of the porous particles and also of the silicon-containing material, formed during the infiltration, with the silicon precursors. This is advantageous for extremely uniform deposition of silicon in pores and on the surface of the porous particles. The most preferred reactors are fluidized bed reactors, rotary tube furnaces or pressure reactors, especially fluidized bed reactors or pressure reactors.

Generally silicon is deposited from the silicon precursors with thermal decomposition. For the silicon infiltration it is possible to use one silicon precursor or a plurality of silicon precursors in the mixture or in alternation. Preferred silicon precursors are selected from silicon-hydrogen compounds, such as monosilane SiH₄, disilane Si₂H₆, and also higher linear, branched or else cyclic homologs, neopentasilane Si₅H₁₂, cyclohexasilane Si₆H₁₂; chlorine-containing silanes, such as trichlorosilane HSiCl₃, dichlorosilane H₂SiCl₂, chlorosilane H₃SiCl, tetrachlorosilane SiCl₄, hexachlorodisilane Si₂Clₛ, and also higher linear, branched or else cyclic homologs such as, for example, 1,1,2,2-tetrachlorodisilane Cl₂HSi-SiHCl₂; chlorinated and part-chlorinated oligosilanes and polysilanes, methylchlorosilanes, such as trichloromethylsilane MeSiCl₃, dichlorodimethylsilane Me₂SiCl₂, chlorotrimethylsilane Me₃SiCl, tetramethylsilane Me₄Si, dichloromethylsilane MeHSiCl₂, chloromethylsilane MeH₂SiCl, methylsilane MeH₃Si, chlorodimethylsilane Me₂HSiCl, dimethylsilane Me₂H₂Si, trimethylsilane Me₃SiH, or else mixtures of the silicon compounds described. Silicon precursors are selected more particularly from monosilane SiH₄, disilane Si₂H₆, chlorine-containing silanes, especially trichlorosilane HSiCl₃, dichlorosilane H₂SiCl₂, chlorosilane H₃SiCl, tetrachlorosilane SiCl₄, hexachlorodisilane Si₂Cl₆ and mixtures comprising these silanes. Monosilane is particularly preferred.

Furthermore, one or more reactive constituents may be introduced into the reactor. Examples of such constituents are dopants based on compounds containing boron, nitrogen, phosphorus, arsenic, germanium, iron or else nickel. The dopants are preferably selected ammonia NH₃, diborane B₂H₆, phosphine PH₃, germane GeH₄, arsine AsH₃, and nickel tetracarbonyl Ni(CO)₄.

Further examples of reactive constituents are hydrogen or else hydrocarbons, more particularly selected from the group encompassing aliphatic hydrocarbons having 1 to 10 carbon atoms, preferably 1 to 6 carbon atoms, such as methane, ethane, propane, butane, pentane, isobutane, hexane, cyclopropane, cyclobutane, cyclopentane, cyclohexane, cycloheptane; unsaturated hydrocarbons having 1 to 10 carbon atoms such as ethylene, acetylene, propylene or butylene; isoprene, butadiene, divinylbenzene, vinylacetylene, cyclohexadiene, cyclooctadiene; cyclic unsaturated hydrocarbons such as cyclopropene, cyclobutene, cyclopentene, cyclohexene, cyclohexadiene, cyclopentadiene, dicyclopentadiene and norbornadiene, aromatic hydrocarbons such as benzene, toluene, p-, m-, and o-xylene, styrene (vinylbenzene), ethylbenzene, diphenylmethane or naphthalene; further aromatic hydrocarbons such as phenol, o-, m-, and p-cresol, cymene, nitrobenzene, chlorobenzene, pyridine, anthracene and phenanthrene, myrcene, geraniol, thioterpineol, norbornane, borneol, isoborneol, bornane, camphor, limonene, terpinene, pinene, pinane, carene, phenol, aniline, anisole, furan, furfural, furfuryl alcohol, hydroxymethylfurfural, bishydroxymethylfuran, and mixed fractions containing a multiplicity of such compounds, for example from natural gas condensates, petroleum distillates, coking oven condensates, mixed fractions from the product streams from a fluid catalytic cracker (FCC), steam cracker or Fischer-Tropsch synthesis plant, or, very generally, hydrocarbon-containing streams from the processing of wood, natural gas, petroleum, and coal.

The process is carried out preferably in an inert gas atmosphere, as for example in a nitrogen or argon atmosphere.

In the process the silicon infiltration is carried out preferably at 280 to 900° C., more preferably at 320 to 600° C., more particularly at 350 to 450° C.

The silicon infiltration may take place under reduced pressure, atmospheric pressure or elevated pressure. The treatment takes place preferably under atmospheric pressure or elevated pressure up to 50 bar.

The process may otherwise be implemented conventionally in a manner common for the infiltration of silicon from silicon precursors, where necessary with routine adaptations that are customary for the skilled person.

A further subject of the invention is an anode material for a lithium-ion battery, which comprises the silicon-carbon composite particles of the invention.

The anode material is based preferably on a mixture comprising the silicon-carbon composite particles of the invention, one or more binders, optionally graphite as further active material, optionally one or more further electrically conducting components, and optionally one or more additives.

The anode material comprises the silicon-carbon composite particles of the invention, preferably one or more binders, optionally graphite as further active material, optionally one or more further electrically conducting components, and optionally one or more additives.

By using further electrically conducting components in the anode material it is possible to reduce the transfer resistances within the electrode and also between electrode and current collector, thereby improving the current-carrying capacity of the lithium-ion battery. Preferred further electrically conducting components are conductive carbon black, carbon nanotubes or metallic particles, copper for example.

The primary particles of conductive carbon black preferably have a volume-weighted particle size distribution between the diameter percentiles of d₁₀ = 5 nm and d₉₀ = 200 nm. The primary particles of conductive carbon black may also have chainlike branching and form structures of up to µm size. Carbon nanotubes preferably have diameters of 0.4 to 200 nm, more preferably 2 to 100 nm, and most preferably 5 to 30 nm. The metallic particles have a volume-weighted particle size distribution which lies between the diameter percentiles of d₁₀ = 5 nm and d₉₀ = 800 nm.

The anode material comprises preferably 0 to 95 wt%, more preferably 0 to 40 wt%, and most preferably 0 to 25 wt% of one or more further electrically conducting components, based on the total weight of the anode material.

The silicon-carbon composite particles of the invention may be present in the anodes for lithium-ion batteries at preferably 5 to 100 wt%, more preferably 30 to 100 wt%, and most preferably 60 to 100 wt%, based on the overall active material present in the anode material.

Preferred binders are polyacrylic acid or the alkali metal salts thereof, more particularly lithium salts or sodium salts, polyvinyl alcohols, cellulose or cellulose derivates, polyvinylidene fluoride, polytetrafluoroethylene, polyolefins, polyimides, especially polyamideimides, or thermoplastic elastomers, especially ethylene-propylene-diene terpolymers. Particularly preferred are polyacrylic acid, polymethacrylic acid or cellulose derivates, especially carboxymethylcellulose. Also particularly preferred are the alkali metal salts, more particularly lithium or sodium salts, of the aforesaid binders. Most preferred are the alkali metal salts, more particularly lithium or sodium salts, of polyacrylic acid or of polymethacrylic acid. All or preferably a fraction of the acid groups in a binder may be present in the form of salts. The binders have a molar mass of preferably 100 000 to 1 000 000 g/mol. Mixtures of two or more binders may also be used.

The graphite used may generally be natural or synthetic graphite. The graphite particles preferably have a volume-weighted particle size distribution between the diameter percentiles of d₁₀ > 0.2 µm and d₉₀ < 200 µm.

Examples of additives are pore formers, dispersants, flow control agents or dopants, an example being elemental lithium.

Preferred formulas for the anode material comprise preferably 5 to 95 wt%, more particularly 60 to 90 wt%, of the silicon-carbon composite particles of the invention; 0 to 90 wt%, more particularly 0 to 40 wt%, of further electrically conducting components; 0 to 90 wt%, more particularly 5 to 40 wt%, of graphite; 0 to 25 wt%, more particularly 5 to 20 wt%, of binders; and optionally 0 to 80 wt%, more particularly 0.1 to 5 wt%, of further additives, with the figures in wt% being based on the total weight of the anode material, and with the fractions of all of the constituents of the anode material adding up to 100 wt%.

A further subject of the invention is an anode which comprises a current collector coated with the anode material of the invention. The anode is used preferably in lithium-ion batteries.

The constituents of the anode material can be processed to given an anode ink or anode paste in a solvent, for example, preferably selected from the group encompassing water, hexane, toluene, tetrahydrofuran, N-methylpyrrolidone, N-ethylpyrrolidone, acetone, ethyl acetate, dimethyl sulfoxide, dimethylacetamide and ethanol, and also mixtures of these solvents, preferably using rotor-stator machines, high-energy mills, planetary kneaders, stirred ball mills, shaker plates or ultrasound appliances.

The anode ink or anode paste has a pH of preferably 2 to 10 (determined at 20° C. using, for example, the WTW pH 340i pH meter with SenTix RJD probe).

The anode ink or anode paste may be knife-coated, for example, onto a copper foil or another current collector. Other coating methods may also be used in the invention, such as, for example, rotational coating (spin coating), roller, dip or slot die coating, painting or spraying.

Before the copper foil is coated with the anode material of the invention, the copper foil may be treated with a commercial primer based, for example, on polymer resins or silanes. Primers can lead to an improvement in the adhesion to the copper, but generally themselves possess virtually no electrochemical activity.

The anode material is dried preferably to constant weight. The drying temperature is guided by the components employed and the solvent used. It is preferably between 20° C. and 300° C., more preferably between 50° C. and 150° C.

The layer thickness, meaning the dry layer thickness of the anode coating, is preferably 2 µm to 500 µm, more preferably from 10 µm to 300 µm.

Lastly, the electrode coatings may be calendered, in order to establish a defined porosity. The electrodes thus produced have porosities preferably of 15 to 85%, which may be determined via mercury porosimetry in accordance with DIN ISO 15901-1. In this case preferably 25 to 85% of the pore volume thus determinable is provided by pores having a pore diameter of 0.01 to 2 µm.

A further subject of the invention is a lithium-ion battery comprising at least one anode which comprises the silicon-carbon composite particles of the invention. The lithium-ion battery may further comprise a cathode, two electrically conducting connections to the electrodes, a separator, and an electrolyte with which the separator and the two electrodes are impregnated, and also a housing accommodating the aforesaid components.

For the purposes of this invention, the term “lithium-ion batteries” also embraces cells. Cells generally encompass a cathode, an anode, a separator, and an electrolyte. Besides one or more cells, lithium-ion batteries preferably further comprise a battery management system. Battery management systems serve generally to control batteries, by means of electronic circuits, for example, particularly for the purpose of recognizing the charging state, for protection from exhaustive discharge or protection from overcharging.

Preferred cathode materials employed may be lithium cobalt oxide, lithium nickel oxide, lithium nickel cobalt oxide (doped or undoped), lithium manganese oxide (spinel), lithium nickel cobalt manganese oxides, lithium nickel manganese oxides, lithium iron phosphate, lithium cobalt phosphate, lithium manganese phosphate, lithium vanadium phosphate or lithium vanadium oxides.

The separator is preferably an electrically insulating membrane permeable to ions, made preferably from polyolefins, as for example polyethylene (PE) or polypropylene (PP), or polyesters, or corresponding laminates. As is customary within battery production, the separator may alternatively be made of or coated with vitreous materials or ceramic materials. As is known, the separator divides the first electrode from the second electrode and so prevents electronically conducting connections between the electrodes (short circuiting).

The electrolyte is preferably a solution comprising one or more lithium salts (i.e., conducting salt) in a aprotic solvent. Preferred conducting salts are those selected from the group containing lithium hexafluorophosphate, lithium hexafluoroarsenate, lithium perchlorate, lithium tetrafluoroborate, lithium imides, lithium methides, LiCF₃SO₃, LiN(CF₃SO₂), and lithium borates. The concentration of the conducting salt, based on the solvent, is preferably between 0.5 mol/l and the solubility limit of the salt in question. More preferably it is 0.8 to 1.2 mol/l.

Examples of solvents which can be used are cyclic carbonates, propylene carbonate, ethylene carbonate, fluoroethylene carbonate, dimethyl carbonate, diethyl carbonate, ethyl methyl carbonate, dimethoxyethane, diethoxyethane, tetrahydrofuran, 2-methyltetrahydrofuran, gamma-butyrolactone, dioxolane, acetonitrile, organic carbonic esters, or nitriles, individually or as mixtures thereof.

The electrolyte preferably comprises a film former, such as vinylene carbonate or fluoroethylene carbonate, for example. In this way a significant improvement can be achieved in the cycling stability of the anodes comprising the silicon-containing material of the invention. This effect is ascribed primarily to the formation of a solid electrolyte interphase on the surface of active particles. The fraction of the film former in the electrolyte is preferably between 0.1 and 20.0 wt%, more preferably between 0.2 and 15.0 wt%, and most preferably between 0.5 and 10 wt%.

In order to achieve the best possible mutual optimization of the actual capacities of the electrodes of a lithium-ion cell, it is advantageous to quantitatively balance the materials for the positive and negative electrodes. Of particular importance in this context is that an outer layer is formed on the surface of the electrochemically active materials in the anode in the course of the first or initial charging/discharging cycle of secondary lithium-ion cells (known as formation). This outer layer is referred to as “solid electrolyte interphase” (SEI) and consists in general of electrolyte decomposition products above all, and also a certain amount of lithium, which is accordingly no longer available for further charging/discharging reactions. The thickness and composition of the SEI are dependent on the nature and quality of the anode material used and of the electrolyte solution used.

The SEI is particularly thin in the case of graphite. On graphite there is a loss of usually 5% to 35% of the mobile lithium in the cell in the first charging step. The reversible capacity of the battery also drops correspondingly.

In the case of anodes with the silicon-carbon composite particles of the invention, the loss of mobile lithium in the first charging step is preferably at most 30%, more preferably at most 20%, and most preferably at most 10%, this being well below the prior-art values described in US 10,147,950 B1, for example, for silicon-containing composite anode materials.

The lithium-ion battery of the invention can be produced in all customary forms, such as in wound, folded or stacked form, for example.

All the materials and substances utilized in producing the lithium-ion battery of the invention, as described above, except for the silicon-carbon composite particles of the invention, are known. The components of the battery of the invention and their assembly to give the battery of the invention take place in accordance with the techniques known in the field of battery production.

The silicon-carbon composite particles of the invention are notable for significantly improved electrochemical behavior and lead to lithium-ion batteries having high volumetric capacities and outstanding performance properties. The silicon-carbon composite particles of the invention are permeable to lithium ions and electrons and so enable charge transport. With the silicon-carbon composite particles of the invention, the amount of amount of SEI in lithium-ion batteries can be greatly reduced. In addition, because of the design of the silicon-carbon composite particles of the invention, the SEI is no longer detached, or is detached at least to a far lesser extent, from the surface of the silicon-carbon composite particles of the invention. All of this results in a high cycling stability of corresponding lithium-ion batteries. Fading and trapping can be minimized. Furthermore, lithium-ion batteries of the invention exhibit little initial and continuous loss of lithium available in the cell, and hence exhibit high coulombic efficiencies.

In the examples below, unless otherwise indicated in each case, all quantities and percentages are given by weight, all pressures are 0.10 MPa (abs.), and are temperatures are 20° C.

### EXAMPLES

The pH values are determined according to ASTM standard number D1512, method A.

### Scanning Electron Microscopy (SEM/EDX)

The microscope studies were carried out using a Zeiss Ultra 55 scanning electron microscope and an Oxford X-Max 80N energy-dispersive X-ray spectrometer. In order to prevent charging phenomena, the samples were vapor-coated with carbon, prior to the study, using a Safematic 010/HV Compact Coating Unit. Cross sections of the silicon-containing materials were produced using a Leica TIC 3X ion cutter at 6 kV.

### Inorganic Analysis/Elemental Analysis

The C contents were determined using a Leco CS 230 analyzer, while a Leco TCH-600 analyzer was used for determining oxygen and nitrogen contents. The qualitative and quantitative determination of other elements, especially the determination of the alkali metals and alkaline earth metals, took place by means of ICP (inductively coupled plasma) emission spectrometry (Optima 7300 DV, from Perkin Elmer). For this purpose the samples underwent acid digestion (HF/HNO₃) in a microwave (Microwave 3000, from Anton Paar). The ICP-OES determination is based on ISO 11885 “Water quality - Determination of selected elements by inductively coupled plasma optical emission spectrometry (ICP-OES) (ISO 11885:2007); German version EN ISO 11885:2009”, which is employed for analysis of acidic aqueous solutions (for example, acidified samples of drinking water, wastewater and other waters, aqua regia extracts from soils and sediments).

### Particle Size Determination

The particle size distribution was determined according to ISO 13320 by means of static laser scattering with a Horiba LA 950. In preparing the samples, particular care must be taken here in dispersing the particles in the measuring solution, so as not to measure the size of agglomerates rather than individual particles. For the materials studied here, they were dispersed in ethanol. Accordingly, prior to the measurement, as and where necessary, the dispersion was ultrasonicated for 4 minutes in a Hielscher laboratory ultrasound instrument, model UIS250v with LS24d5 sonotrode, at 250 W.

### BET Surface Area Measurement

The specific surface area of the materials was measured via gas adsorption with nitrogen using a Sorptomatic 199090 instrument (Porotec) or SA-9603MP instrument (Horiba) in accordance with the BET method (determination according to DIN ISO 9277:2003-05 with nitrogen).

### Skeletal Density

The skeletal density, meaning the density of the porous solid based on the volume exclusively of the pore spaces accessible to gas from outside, was determined by means of helium pycnometry according to DIN 66137-2.

### Gas-Accessible Pore Volume (Gurvich Pore Volume)

The gas-accessible pore volume according to Gurvich was determined by gas sorption measurements with nitrogen according to DIN 66134.

In inventive examples 1 - 6 below and also in comparative example 1, the production and properties of the porous carbon particles used for producing the silicon-carbon composite particles of the invention are described.

Comparative example 1: Porous carbon particles having an alkali/alkaline earth metal concentration < 0.1 wt% and a pH < 7.5.

Porous carbon particles having the following properties were used:
BET surface area: 2140 m²/g
Gurvich PV: 1.01 cm³/g
Na content: 25 ppm
K content: 115 ppm
pH= 5.4

Inventive example 1: Treatment of porous carbon particles with 1-molar NaOH solution.

A 250 ml flask was charged with 20 g of carbon from comparative example 1 and admixed at room temperature with 160 ml of 1M NaOH (aqueous solution). The suspension was then heated to 100° C. and boiled at reflux for 3 hours. After cooling to ambient temperature, the suspension was filtered through a suction filter and the solid product was washed with distilled water until the wash water had a pH of 7. The resulting powder, lastly, was dried overnight in a vacuum drying cabinet at 80° C. and 10⁻² bar. This gave 19.6 g of a black solid.

Inventive example 2: Treatment of porous carbon particles with 1-molar NaOH solution and an additional washing step.

After treatment of the porous carbon particles as in inventive example 1, the sample was additionally washed with 2 L of distilled water. The resulting powder, lastly, was dried overnight in a vacuum drying cabinet at 80° C. and 10⁻² bar. This gave 19.4 g of a black solid.

Inventive example 3: Treatment of porous carbon particles with 1-molar NaOH solution at room temperature.

A 250 ml flask was charged with 20 g of carbon from comparative example 1 and admixed at room temperature with 160 ml of 1 M NaOH (aqueous solution). The suspension was then stirred at room temperature for 1 h and subsequently filtered through a suction filter, and the solid product was washed with distilled water until the wash water had a pH of 7. The resulting powder, lastly, was dried overnight in a vacuum drying cabinet at 80° C. and 10⁻² bar. This gave 19.5 g of a black solid.

Inventive example 4: Treatment of porous carbon particles with NaOH solution at room temperature without washing.

A 250 ml flask was charged with 20 g of carbon from comparative example 1 and admixed at room temperature with NaOH solution (0.4424 g of NaOH in 50 ml of distilled water). The suspension was then stirred at room temperature for 1 h and subsequently filtered through a suction filter. The resulting powder, lastly, was dried overnight in a vacuum drying cabinet at 80° C. and 10⁻² bar. This gave 19.5 g of a black solid.

Inventive example 5: Treatment of porous carbon particles with 1 M LiOH at room temperature. A 250 ml flask was charged with 20 g of carbon from comparative example 1 and admixed at room temperature with 160 ml of 1M LiOH (aqueous solution). The suspension was then heated to 100° C. and boiled under reflux for 3 hours. After cooling to ambient temperature, the suspension was filtered through a suction filter, and the solid product was washed with distilled water until the wash water had a pH of 7. The resulting powder, lastly, was dried overnight in a vacuum drying cabinet at 80° C. and 10⁻² bar. This gave 19.6 g of a black solid.

Inventive example 6: Treatment of porous carbon particles with 1 M KOH at room temperature.

A 250 ml flask was charged with 20 g of carbon from comparative example 1 and admixed at room temperature with 160 ml of 1M KOH (aqueous solution). The suspension was then heated to 100° C. and boiled under reflux for 3 hours. After cooling to ambient temperature, the suspension was filtered through a suction filter, and the solid product was washed with distilled water until the wash water had a pH of 7. The resulting powder, lastly, was dried overnight in a vacuum drying cabinet at 80° C. and 10⁻² bar. This gave 19.6 g of a black solid.

The physical properties of the porous carbon particles are summarized in Table 1 below.

TABLE 1

| | BET surface area [m²/g] | Gurvich pore volume [cm³/g] | Metal content [%/ion] | pH value |
|---|---|---|---|---|
| Comparative example 1 * | 2140 | 1.01 | 0.0025 / Na 0.0115 / K | 5.4 |
| Inventive example 1 | 2010 | 0.95 | 1.2 / Na | 10.7 |
| Inventive example 2 | 1980 | 0.98 | 0.57 / Na | 9.0 |
| Inventive example 3 | 1940 | 0.96 | 1.3 / Na | 10.7 |
| Inventive example 4 | 1900 | 0.94 | 1.2 / Na | 9.8 |
| Inventive example 5 | 2030 | 0.95 | 0.36 / Li | 9.8 |
| Inventive example 6 | 1990 | 0.93 | 2.03 / K | 9.4 |

*not inventive

### Production of Silicon-Carbon Composite Particles

Comparative example 1A: Silicon-carbon composite particles from porous carbon particles from comparative example 1.

A tubular reactor was charged with 3.0 g of the porous carbon particles from comparative example 1 (specific surface area = 2140 m²/g, Gurvich pore volume = 1.01 cm³/g, pH = 5.4) in a fused silica boat. After having been rendered inert with nitrogen, the reactor was heated to 410° C. When the reaction temperature had been reached, the reactive gas (10% SiH₄ in N₂, 10 L (STP)/h) was passed through the reactor for 4.9 h. The reactor was subsequently flushed with inert gas and cooled to room temperature, and the product was removed.

Comparative example 1B: Silicon-carbon composite particles from porous carbon particles from comparative example 1 at reduced temperature.

A tubular reactor was charged with 3.0 g of the porous carbon from comparative example 1 (specific surface area = 2140 m²/g, Gurvich pore volume = 1.01 cm³/g, pH = 5.4) in a fused silica boat. After having been rendered inert with nitrogen, the reactor was heated to 380° C. When the reaction temperature had been reached, the reactive gas (10% SiH₄ in N₂, 10 L (STP)/h) was passed through the reactor for 10.2 h. The reactor was subsequently flushed with inert gas and cooled to room temperature, and the product was removed.

Inventive example 1A: Silicon-carbon composite particles from porous carbon particles from inventive example 1.

A tubular reactor was charged with 3.0 g of the porous carbon particles from inventive example 1 (specific surface area = 2010 m²/g, Gurvich pore volume = 0.95 cm³/g, pH = 10.7) in a fused silica boat. After having been rendered inert with nitrogen, the reactor was heated to 380° C. When the reaction temperature has been reached, the reactive gas (10% SiH₄ in N₂, 10 L (STP)/h) was passed through the reactor for 4.6 h. The reactor was subsequently flushed with inert gas and cooled to room temperature, and the product was removed.

Inventive example 2A: Silicon-carbon composite particles from porous carbon particles from inventive example 2.

A tubular reactor was charged with 3.0 g of the porous carbon particles from inventive example 2 (specific surface area = 1980 m²/g, Gurvich pore volume = 0.98 cm³/g, pH = 9.0) in a fused silica boat. After having been rendered inert with nitrogen, the reactor was heated to 380° C. When the reaction temperature had been reached, the reactive gas (10% SiH₄ in N₂, 10 L (STP)/h) was passed through the reactor for 8.5 h. The reactor was subsequently flushed with inert gas and cooled to room temperature, and the product was removed.

Inventive example 3A: Silicon-carbon composite particles from porous carbon particles from inventive example 3.

A tubular reactor was charged with 3.0 g of the porous carbon particles from inventive example 3 (specific surface area = 1940 m²/g, Gurvich pore volume = 0.96 cm³/g, pH = 10.7) in a fused silica boat. After having been rendered inert with nitrogen, the reactor was heated to 380° C. When the reaction temperature had been reached, the reactive gas (10% SiH₄ in N₂, 10 L (STP)/h) was passed through the reactor for 5.4 h. The reactor was subsequently flushed with inert gas and cooled to room temperature, and the product was removed.

Inventive example 4A: Silicon-carbon composite particles from porous carbon particles from inventive example 4.

A tubular reactor was charged with 3.0 g of the porous carbon particles from inventive example 4 (specific surface area = 1900 m²/g, Gurvich pore volume = 0.94 cm³/g, pH = 9.8) in a fused silica boat. After having been rendered inert with nitrogen, the reactor was heated to 380° C. When the reaction temperature had been reached, the reactive gas (10% SiH₄ in N₂, 10 L (STP)/h) was passed through the reactor for 5.7 h. The reactor was subsequently flushed with inert gas and cooled to room temperature, and the product was removed.

Inventive example 5A: Silicon-carbon composite particles from porous carbon particles from inventive example 5.

A tubular reactor was charged with 3.0 g of the porous carbon particles from inventive example 5 (specific surface area = 2030 m²/g, Gurvich pore volume = 0.95 cm³/g, pH = 9.8) in a fused silica boat. After having been rendered inert with nitrogen, the reactor was heated to 380° C. When the reaction temperature had been reached, the reactive gas (10% SiH₄ in N₂, 10 L (STP)/h) was passed through the reactor for 7.1 h. The reactor was subsequently flushed with inert gas and cooled to room temperature, and the product was removed.

Inventive example 6A: Silicon-carbon composite particles from porous carbon particles from inventive example 6.

A tubular reactor was charged with 3.0 g of the porous carbon particles from inventive example 6 (specific surface area = 1990 m²/g, Gurvich pore volume = 0.93 cm³/g, pH = 9.4) in a fused silica boat. After having been rendered inert with nitrogen, the reactor was heated to 380° C. When the reaction temperature had been reached, the reactive gas (10% SiH₄ in N₂, 10 L (STP)/h) was passed through the reactor for 8.0 h. The reactor was subsequently flushed with inert gas and cooled to room temperature, and the product was removed.

Inventive example 7A: Silicon-carbon composite particles from porous carbon particles from inventive example 1 by reaction in a pressure reactor.

The reaction was carried out using an electrically heated autoclave consisting of a cylindrical bottom part (beaker) and a lid with a number of connections (for gas supply, gas removal, temperature measurement and pressure measurement, for example) having a volume of 594 ml. The stirrer used was a very close-clearance helical stirrer. The height of this stirrer corresponded to about 50% of the clear height of the reactor interior. The helical stirrer was constructed such that it allowed temperature measurement directly in the bed. The autoclave was charged with 10.0 g of the porous carbon from inventive example 1 (specific surface area = 2010 m²/g, Gurvich pore volume = 0.95 cm³/g, pH = 10.7) and closed. The autoclave was first evacuated. Then SiH₄ (15.6 g) was injected with a pressure of 15.1 bar. Thereafter the autoclave was heated over 90 minutes to a temperature of 425° C., the temperature being held for 240 minutes. In the course of the reaction, the pressure rose to 76 bar. Over the course of 12 hours, the autoclave cooled down to room temperature (21° C.). After cooling a pressure of 35 bar remained in the autoclave. The pressure in the autoclave was reduced to 1 bar and it was then flushed five times with nitrogen, five times with lean air having an oxygen fraction of 5%, five times with lean air having an oxygen fraction of 10%, and subsequently five times with air. An amount of 21.3 g of silicon-carbon composite particles was isolated in the form of a fine black solid.

The reaction conditions for producing the silicon-carbon composite particles, and the physical properties of said particles, are summarized in Table 2 below.

TABLE 2

| | Temperature [°C] | Reaction time [h] | BET surface area [m²/g] | Silicon content [wt%] | Metal ion concentration [% / ion] | pH |
|---|---|---|---|---|---|---|
| Comp. example 1A* | 410 | 4.9 | 10 | 57 | < 0.0010 / Na 0.0053 / K | 6.0 |
| Comp. example 1B* | 380 | 10.2 | 27 | 57 | 0.0037 / Na < 0.0025 / K | 6.1 |
| Inventive example 1A | 380 | 4.6 | 35 | 49 | 0.53 / Na | 9.7 |
| Inventive example 2A | 380 | 8.5 | 26 | 54 | 0.25 / Na | 9.3 |
| Inventive example 3A | 380 | 5.4 | 74 | 52 | 0.55 / Na | 10.1 |
| Inventive example 4A | 380 | 5.7 | 58 | 50 | 0.5 / Na | 9.8 |
| Inventive example 5A | 380 | 7.1 | 32 | 51 | 0.16 / Li | 9.8 |
| Inventive example 6A | 380 | 8.0 | 31 | 54 | 0.86 / K | 9.6 |
| Inventive example 7A | n.a. | n.a. | 15 | 55 | 0.55 / Na | 9.5 |

*not inventive

The data for the production of the silicon-carbon composite particles of the invention clearly indicate that the infiltration of silicon when employing the process of the invention for production from porous carbon particles having an alkali metal concentration > 0.05 wt% and a pH of greater than 7.5, advantageously, takes place much faster.

### Evaluation of the Silicon-Carbon Composite Particles in Electrochemical Cells

Inventive example 8: Anode comprising silicon-carbon composite particles of the invention from inventive example 1A and electrochemical testing in a lithium-ion battery.

29.71 g of polyacrylic acid (dried to constant weight at 85° C.; Sigma-Aldrich, Mw ~450 000 g/mol) and 756.60 g of deionized water were agitated by means of shaker (2901 /min) for 2.5 h until the polyacrylic acid was fully dissolved. Added in portions to the solution was lithium hydroxide monohydrate (Sigma-Aldrich) until the pH was 7.0 (measured using WTW pH 340i pH meter and SenTix RJD probe). The solution was subsequently mixed together by shaker for a further 4 h. 3.87 g of the neutralized polyacrylic acid solution and 0.96 g of graphite (Imerys, KS6L C) were introduced into a 50 ml vessel and combined in a planetary mixer (SpeedMixer, DAC 150 SP) at 2000 rpm. Then 3.40 g of the silicon-carbon composite particles of the invention from inventive example 1A were stirred in at 2000 rpm for 1 min. Next 1.21 g of an 8 percent conductive carbon black dispersion and 0.8 g of deionized water were added and were incorporated on the planetary mixer at 2000 rpm. This was followed by dispersion in a dissolver at 3000 rpm for 30 minutes at a constant 20° C. The ink was subsequently degassed again in the planetary mixer at 2500 rpm for 5 min under reduced pressure.

The completed dispersion was then applied using a film-drawing frame with a 0.1 mm gap height (Erichsen, model 360) to a copper foil with a thickness of 0.03 mm (Schlenk Metallfolien, SE-Cu58). The anode coating produced in this way was subsequently dried for 60 min at 60° C. and air pressure 1 bar. The mean weight per unit area of the dry anode coating was 2.2 mg/cm² and the coating density was 0.8 g/cm³.

The electrochemical studies were carried out on a button cell (CR2032 type, Hohsen Corp.) in a two-electrode arrangement. The electrode coating was used as counterelectrode or negative electrode (Dm = 15 mm), a coating based on lithium nickel manganese cobalt oxide 6:2:2 with a content of 94.0% and a mean weight per unit area of 15.9 mg/cm² (sourced from the company SEI) was used as working electrode or positive electrode (Dm = 15 mm). A glass fiber filter paper (Whatman, GD Type D) soaked with 60 µl of electrolyte served as the separator (Dm = 16 mm). The electrolyte used consisted of a 1.0-molar solution of lithium hexafluorophosphate in a 1:4 (v/v) mixture of fluoroethylene carbonate and diethyl carbonate. The cell was constructed in a glovebox (< 1 ppm H₂O, O₂); the water content in the dry mass of all the components used was below 20 ppm.

The electrochemical testing was carried out at 22° C. The cell was charged by the cc/cv (constant current / constant voltage) method with a constant current of 15 mA/g (corresponding to C/10) in the first cycle and of 75 mA/g (corresponding to C/2) in the subsequent cycles, and, on attainment of the voltage limit of 4.2 V, at constant voltage until the current went below 1.5 mA/g (corresponding to C/100) or 3 mA/g (corresponding to C/50). The cell was discharged by the cc (constant current) method with a constant current of 15 mA/g (corresponding to C/10) in the first cycle and of 75 mA/g (corresponding to C/2) in the subsequent cycles, until the voltage limit of 2.5 V was attained. The specific current chosen was based on the weight of the coating of the positive electrode. The electrodes were selected such as to establish a cathode:anode capacity ratio of 1:1.2.

Inventive example 9: Anode comprising silicon-carbon composite particles of the invention from inventive example 5A, and electrochemical testing in a lithium-ion battery.

The silicon-containing material of the invention from inventive example 5A was used to produce an anode as described in inventive example 8. As described in inventive example 8, the anode was built up to a lithium-ion battery and subjected to the same testing procedure.

Inventive example 10: Anode comprising silicon-carbon composite particles of the invention from inventive example 6A, and electrochemical testing in a lithium-ion battery.

The silicon-containing material of the invention from inventive example 6A was used to produce an anode as described in inventive example 8. As described in inventive example 8, the anode was built up to a lithium-ion battery and subjected to the same testing procedure.

Comparative example 11: Anode comprising silicon-carbon composite particles of the invention from inventive example 6A, and electrochemical testing in a lithium-ion battery. The noninventive silicon-containing material from comparative example 1A was used to produce an anode as described in inventive example 8. As described in inventive example 8, the anode was built up to a lithium-ion battery and subjected to the same testing procedure.

The results from the electrochemical evaluations are summarized in Table 3 below.

TABLE 3

| | Rev. capacity in the second cycles [mAh/g] | Cycle with 80% capacity retention |
|---|---|---|
| Inventive example 8 | 1000 | 759 |
| Inventive example 9 | 1200 | 546 |
| Inventive example 10 | 1200 | 775 |
| Comparative example 11* | 1250 | 224 |

*not inventive

It is clearly apparent that significantly higher cycling stabilities can be achieved by means of the silicon-carbon composite particles of the invention than with conventional silicon-carbon composite particles.

What is claimed is:

1-14. (canceled)

15. Silicon carbon composite particles, comprising:
a) an alkali metal or alkaline earth metal concentration of 0.05 to 10 wt%; and
b) a pH > 7.5.

16. The silicon carbon composite particles of claim 15, wherein the silicon carbon composite particles have a volume-weighted particle size distribution with diameter percentiles d₅₀ of 0.5 to 20 µm.

17. The silicon carbon composite particles of claim 15, wherein the silicon carbon composite particles have at least 30 wt% of silicon obtained by silicon infiltration.

18. The silicon carbon composite particles of claim 15, wherein in pores and on the outer surface of the silicon carbon composite particles silicon is present in the form of layers, or in the form of layers formed from silicon particles, having a thickness of at most 1 µm.

19. The silicon carbon composite particles of claim 15, wherein the silicon carbon composite particles have a specific BET surface area of at most 100 m²/g.

20. The silicon carbon composite particles of claim 17, wherein the silicon carbon composite particles have a pore volume P which is at least 100 vol%, based on the volume of the silicon obtained from silicon infiltration in the silicon carbon composite particles, the pore volume P of the silicon carbon composite particles resulting from the sum total of gas-accessible and gas-inaccessible pore volume.

21. The silicon carbon composite particles of claim 15, wherein the silicon carbon composite particles are used in an anode material of a lithium-ion battery.

22. A process for producing the silicon carbon composite particles, comprising:
providing silicon carbon composite particles having an alkali metal or alkaline earth metal concentration of 0.05 to 10 wt% and a pH > 7.5 by silicon infiltration from silicon precursors which are selected from silicon precursors which are liquid or gaseous at 20° C. and 1013 mbar, in the presence of porous carbon particles, wherein the porous carbon particles, by treatment with a basic alkali metal or alkaline earth metal compound in a molar ratio of 100:1 to 5:1, based on the carbon present in the porous carbon particles, have an alkali metal or alkaline earth metal concentration of 0.1 to 20 wt% and a pH of > 7.5.

23. The process of claim 22, wherein the silicon infiltration takes place in a reactor selected from fluidized bed reactors, rotary tube furnaces arranged horizontally through vertically, open or closed fixed-bed reactors, and pressure reactors.

24. The process of claim 22, wherein silicon infiltration is carried out at 280 to 900° C.

25. The process of claim 22, wherein the silicon carbon composite particles are produced by silicon infiltration from silanes selected from monosilane and chlorine-containing silanes.

26. An anode material for a lithium-ion battery, comprising:
wherein the anode material comprises the silicon carbon composite particles having an alkali metal or alkaline earth metal concentration of 0.05 to 10 wt% and a pH > 7.5.

27. The anode material for a lithium-ion battery of claim 26, wherein the anode material is coated on a current collector.
